(19) United States
(12) Patent Application Publication
(10) Pub. No.: US 2012/0000104 A1
(43) Pub. Date: Jan. 5, 2012

(54) LED STRIP FOR SMALL CHANNEL LETTERS

(75) Inventors: Henricus Marie Peeters, Baarlo (NL); Waltherus Emericus Johannes Van Gompel, Eersel (NL); Willibrordus Adrianus Johannes Antonius Van Der Poel, Veldhoven (NL)

(73) Assignee: KONINKLIJKE PHILIPS ELECTRONICS N.V., EINDHOVEN (NL)

(21) Appl. No.: 13/255,020

(22) PCT Filed: Mar. 11, 2010
(86) PCT No.: PCT/IB2010/051057

§ 371 Date: Sep. 6, 2011

(30) Foreign Application Priority Data
Mar. 17, 2009 (EP) 09155387.5

(51) Int. Cl. G09F 13/00; H01L 33/52; F21S 4/00; H01L 27/15

(52) U.S. Cl. 40/541; 257/88; 438/28; 257/E27.121; 257/E33.059

(57) ABSTRACT

A light emitting diode, LED, strip (301) for the illumination of channel signs is provided. The LED strip comprises a flexible circuit board, a plurality of LEDs mounted on the circuit board, and an electrical connector for connecting the LED strip to a power supply. The LED strip is at least in part encapsulated by a flexible resin such that the LED strip is foldable. The LED strip according to the present invention is advantageous in that its length can be adjusted by folding instead of cutting, thereby retaining the waterproof encapsulation of the LED strip. Further, a method for mounting a flexible LED strip (301) in a channel sign is provided. The method comprises the steps of attaching at least one clip (302) to an interior surface (303) of the channel sign, folding back an end (304) of the LED strip, and fixating the LED strip including the folded end using the clip. The method according to the present invention is advantageous in that it provides an easier and more reliable mounting of a LED strip as compared to standard prior art techniques.

### FIELD OF THE INVENTION

The invention relates to LED strips for the illumination of channel signs that are used in lighting displays for shops and advertising.

### BACKGROUND OF THE INVENTION

Illuminated channel signs are commonly used for advertising. Shops and warehouses, e.g., use such signs to advertise their brand name or logotype to customers. Because of the huge variety of typefaces used and the individual character of such signs, they are generally custom made. In the past, neon tubes were frequently used, but in recent years light emitting diode (LED) based arrangements have become increasingly popular.

Neon tubes have numerous disadvantages, which makes them expensive to use. For example, their shape has to be customized, thereby increasing their price and thus the price of the channel sign. Further, neon tubes are very fragile and thus difficult to transport. Furthermore, neon tubes have to be installed and electrically connected when the sign is mounted, which makes it difficult to achieve a waterproof arrangement.

LEDs, on the other hand, are less expensive and less fragile. Another advantage of LEDs is that their lifetime is much larger than that of neon tubes and exceeds 50.000 hrs. The current arrangements employing LEDs are manifold. Some arrangements incorporate printed circuit boards (PCB) with a shape adapted to the signs they are destined to illuminate. Such custom made arrangements are, however, costly since each sign requires a different PCB. Also, providing a waterproof arrangement is tedious because of the generally large illuminated area of such signs that require correspondingly large PCBs.

Arrangements that employ interconnected LED modules do not require custom made parts. The modules are mounted in a channel sign and electrically connected to a power supply. However, such arrangements are difficult to mount in small signs that have a channel that is only a few centimeters wide.

U.S. Pat. No. 6,478,450 discloses a lighting system for channel signs comprising a flexible conductor strip that can be mounted to a structure of a channel sign and to which light sources, e.g., LEDs, can be electrically connected. The disadvantage of such a lighting system is that it is difficult to make it waterproof.

### SUMMARY OF THE INVENTION

It is an object of the present invention to provide a more efficient alternative to the above techniques and prior art.

More specifically, it is an object of the present invention to provide an improved waterproof LED strip for channel signs that is easy to mount.

These and other objects of the present invention are achieved by means of a LED strip having the features defined in independent claim 1, and by means of a method for mounting a LED strip defined in independent claim 6. Embodiments of the invention are characterized by the dependent claims.

Hence, according to a first aspect of the present invention, a LED strip for channel signs is provided. The LED strip comprises a flexible circuit board (FCB), a plurality of LEDs, and an electrical connector. The LEDs are mounted and electrically connected to the FCB. The connector may be used to connect the LED strip to a power supply. The LED strip is at least in part encapsulated by a flexible resin such that the LED strip is foldable.

According to a second aspect of the invention, a method for mounting a flexible LED strip in a channel sign is provided. The method comprises the steps of attaching at least one clip to an interior surface of the channel sign, folding back an end of the LED strip, and fixating the LED strip including the folded end using the clip.

The present invention makes use of an understanding that the LED strip according to the first aspect of the invention may comprise an FCB with LEDs mounted to it, and a connector or means for electrically connecting the LED strip to a power supply. In order to achieve a waterproof solution, the LED strip is at least in part encapsulated in a flexible resin, which is applied such that the LED strip is foldable. Thus, if a LED strip is too long for a particular channel sign or part of a channel sign, the present invention is advantageous in that the LED strip can be folded between two adjacent LEDs. In other words, the length of the LED strip can be adjusted by folding.

Further, the present invention is advantageous in that, as compared to prior art techniques where the LED strip needs to be cut to adjust its length, the waterproof encapsulation is retained by folding the LED strip.

The method according to the second aspect of the invention is advantageous in that an easier and more reliable mounting of a LED strip in a channel sign is provided by fixating the LED strip using clips attached to the interior surface of a channel sign. The same clips can be used to fixate a folded-back end of the LED strip. As compared to prior art techniques using glue or self-adhesive tape, the use of clips presents the advantage that the LED strip is more reliably mounted and that its position can be corrected afterwards. The use of clips facilitates also the replacement of a defective LED strip, or if the LED strip should be replaced for any other reason.

According to an embodiment of the invention, the LED strip according to the first aspect of the invention may comprise additional electronic components mounted to the FCB such that at least one region between two adjacent LEDs is free from any electronic components. Having a region that is free from electronic components allows the LED strip to be folded at that region. More than one region that is free from electronic components can be achieved by mounting all additional electronic components close to one or several of the LEDs, thereby achieving a LED strip that is adjustable to a range of lengths.

According to an embodiment, the flexible resin is applied to the LED strip according to the first aspect of the invention only where electronic components, including LEDs, are mounted, whereas at least one region between adjacent LEDs is not encapsulated with resin. In that way the electronic components are protected from moisture while, at the same time, the LED strip is foldable at regions where no resin (or, at least, almost no resin) is applied.

According to another embodiment, the flexible resin that the LED strip according to the first aspect of the invention is encapsulated with is thinner at regions between LEDs, where no electronic components are mounted, than at the LEDs. In that way the electronic components are protected from moisture while, at the same time, the thinner resin between the LEDs facilitates a folding of the LED strip.

According to an embodiment of the invention, the LED strip as described above may be arranged in a channel sign. For this purpose, the channel sign further comprises at least one clip that is attached to an interior surface of the channel sign.

For the purpose of describing the present invention, it is assumed that a channel sign is box-shaped (e.g., a channel sign having a rectangular cross section) and comprises a front wall (which is, e.g., letter shaped), a rear wall that is facing the front wall (preferably substantially parallel, but not necessarily), and side walls connecting the front wall and the rear wall. Preferably, the walls are arranged in order to form an enclosed surface. Further, it is assumed that the front wall is exposed for reading and is at least transparent or translucent for the light emitted by LED strip mounted inside the channel sign. However, with respect to the present invention, a channel is not limited to the shape described above but can have any shape. Furthermore, any one of the walls of a channel sign may be exposed to reading, i.e., configured to emit light. For example, both the front and the rear walls may be exposed for reading.

According to an embodiment of the method according to the second aspect of the invention, the clip is attached to an interior side wall of the channel sign. Mounting the LED strip to a side wall of a channel sign has the advantage that no extra diffuser is needed in order to create a homogenous light distribution. Indeed, the channel itself acts as a mixing chamber by reflecting light from the interior surfaces such as the rear wall and the side walls. In that way, the occurrence of so-called bright spots, caused by individual light sources that are visible through the front wall of the channel sign, is reduced. Furthermore, the FCB adapts more easily to a curvature if mounted on the curved side wall of a channel sign than on the rear wall. Mounting on the side wall is also advantageous in signs that emit light through both the front wall and the rear wall, since the emitted light is not obstructed by clips, self-adhesive tape, or screws. This is the case, e.g., in signs that create a halo on a wall behind the sign, or signs that can be viewed from both sides.

According to another embodiment of the method according to the second aspect of the invention, the clip is attached using self-adhesive tape. The use of self-adhesive tape for attaching the clip to an interior surface is advantageous in that the number of tools required for mounting a LED strip is reduced. For example, no drilling machine is needed. Furthermore, in small channel signs, the use of a screw driver is hampered by the small space that is available.

According to further embodiments of the method according to the second aspect of the invention, the clips are specifically adapted to be attached to a curved surface, such as a wall of a channel sign. The clip can, e.g., have a base of elongated shape or a split base comprising two elongated parts.

Further objectives of, features of, and advantages with, the present invention will become apparent when studying the following detailed disclosure, the drawings and the appended claims. Those skilled in the art realize that different features of the present invention can be combined to create embodiments other than those described in the following.

### BRIEF DESCRIPTION OF THE DRAWINGS

The above, as well as additional objects, features and advantages of the present invention, will be better understood through the following illustrative and non-limiting detailed description of embodiments of the present invention, with reference to the appended drawings, in which:

FIG. 1 shows a LED strip with resin applied only where electronic components are mounted, in accordance with an embodiment of the present invention.

FIG. 2 shows a LED strip which has thinner resin in regions between adjacent LEDs than at the LEDs, in accordance with another embodiment of the present invention.

FIG. 3 shows a LED strip with a folded-back end that is fixated using a clip on an interior surface, in accordance with an embodiment of the present invention.

FIGS. 4a to 4c show examples of clips, in accordance with embodiments of the present invention.

FIGS. 5a to 5c illustrate a method for mounting a LED strip using clips, in accordance with an embodiment of the present invention.

FIG. 6 shows a channel sign with a LED strip mounted to an interior wall of the channel sign, in accordance with an embodiment of the present invention.

FIG. 7 shows a LED strip encapsulated in a protective sleeve or tube with a folded-back end that is fixated using a clip on an interior surface of a channel sign, in accordance with an embodiment of the present invention.

All the figures are schematic, not necessarily to scale, and generally only show parts which are necessary in order to elucidate the invention, wherein other parts may be omitted or merely suggested.

### DETAILED DESCRIPTION OF EMBODIMENTS

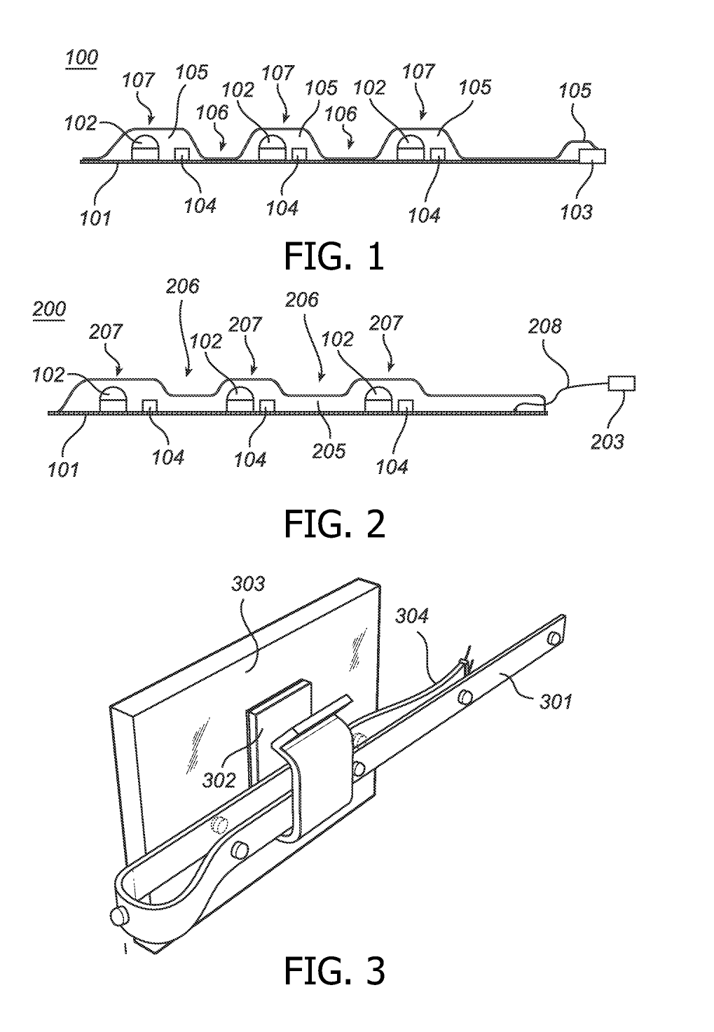

FIG. 1 shows a LED strip 100 for channel signs according to an embodiment of the invention. The LED strip comprises a flexible circuit board (FCB) 101 that has the form of a strip, and a plurality of LEDs 102 mounted to it. A purpose of the FCB 101 is to electrically connect the LEDs 102 mounted to it such that an electrical current can be supplied to the LEDs 102. The FCB 101 is flexible such that the LED strip 100 can adjust to the shape of the channel sign, i.e., to curved surfaces and corners. The LEDs 102 can be of any type that is suitable for mounting to an FCB, e.g., surface mounted devices. A plurality of LEDs mounted to an FCB can be of the same type or of different types, e.g., being of different size or emitting light of different color or intensity.

The LED strip 100 further comprises an electrical connector (or connecting means) 103 for connecting the LED strip 100 to a power supply such that current can be passed through the LEDs 102. The connector 103 can be connected directly to the FCB, e.g., by soldering. The connector 103 can be of any type suitable for the application at hand, either custom made or of a standard type, and can also be of a waterproof type (e.g., IP66). The LED strip 100 may also comprise a plurality of connectors, e.g., one connector at each end of the strip, in order to connect a plurality of LED strips 100 with each other and to a common power supply.

The LED strip 100 is at least in part encapsulated in flexible resin 105 to protect the electronic components and connections, including the LEDs 102 and the connector 103 mounted to the FCB 101, from moisture. In other words, the resin constitutes a waterproof encapsulation. The resin 105 is applied such that the LED strip 100 is foldable at regions 106 between adjacent LEDs 102. This can be achieved, as shown in FIG. 1, by applying resin 105 only at regions 107 where electronic components, including LEDs 102 and connector 103, are mounted.

With reference to FIG. 2, another embodiment of the invention is described that is similar to the LED strip 100 described with reference to FIG. 1. The LED strip 200, however, has a resin encapsulation 205 that is thinner at regions 206 between adjacent LEDs 102 than at regions 207 where the LEDs 102 are located, instead of having regions that are free from resin 105 between adjacent LEDs 102, such as described with reference to FIG. 1.

With reference to FIG. 2, an alternative means for electrically connecting the LED strip 200 is described. Instead of mounting an electrical connector directly to the FCB 101, as described with reference to FIG. 1, wires 208 can be electrically connected to the FCB 101, e.g., by soldering. The wires 208 can be used to electrically connect the LED strip 200 to a power supply, either directly or through a connector 203 attached to the wires 208. The wires 208 can be of a standard type and are preferably insulated. The connector 203 can be of any type suitable for the application at hand, either custom made or of a standard type, and can also be of a waterproof type (e.g., IP66). It will be appreciated that the alternative means for electrically connecting the LED strip described with reference to FIG. 2 may replace the connector 103 in the LED strip 100 described with reference to FIG. 1, and vice versa.

Regions 106 that are free from resin 105 or regions 206 where the resin 205 is thinner can be located between each pair of adjacent LEDs 102 or just between one or a few pairs. Depending on the number of regions where the strip is foldable, virtually any length can be achieved with only a few LED strips of different lengths.

The resin that is used for encapsulation is preferably at least transparent or translucent. It might also be colored or patterned to achieve a desired illumination effect. Silicon resin can, e.g., be used since it is UV resistant, does not discolor, and does not become porous.

In addition to the LEDs 102, additional electronic components 104 can be mounted to the FCB 101. They can be used, e.g., for the purpose of supplying current to the LEDs 102 or controlling the LEDs 102 such that a desired illumination effect is obtained. If, e.g., the LED strip comprises LEDs of different colors, electronics can be provided to allow for illumination of varying color. The additional electronic components 104 are preferably mounted in the vicinity of one or several of the LEDs 102 in order not to impede folding of the LED strip.

In FIG. 3 it is illustrated how a LED strip 301 can be folded back at regions between adjacent LEDs 102. The LED strip 301 may be equivalent to any one of the LED strips 100 or 200 described with reference to FIGS. 1 and 2, respectively. In that way, the length of the LED strip 301 can be adjusted to virtually any length, depending on the number and placement of regions where the LED strip 301 is foldable, i.e., regions 106 where no resin is applied or regions 206 where the resin encapsulation is thinner. FIG. 3 also illustrates how to mount a LED strip 301 in a channel sign using a clip 302 that is attached to an interior wall 303 of the channel sign. The same clip 302 that is used to mount the LED strip 301 in a channel sign can also be used to fixate a folded-back end 304 of the LED strip 301. Fixating a LED strip is facilitated by the regions 106 and 206 between adjacent LEDs 102 where no resin 105 is applied, as shown in FIG. 1, or where the resin 205 is thinner, as shown in FIG. 2, respectively. Since the LED strip 301 is thinner in these regions it is easier to insert them into an opening of the clip 302. Furthermore, since no electronic components are mounted in these regions, the risk of damaging the LED strip is reduced.

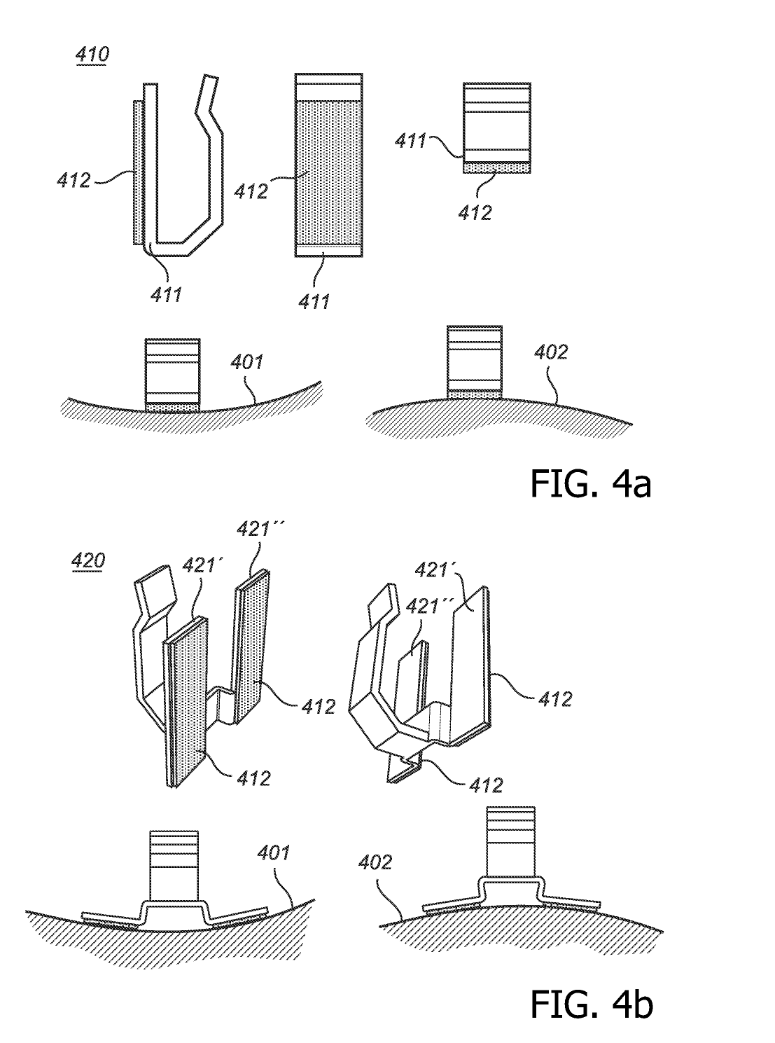

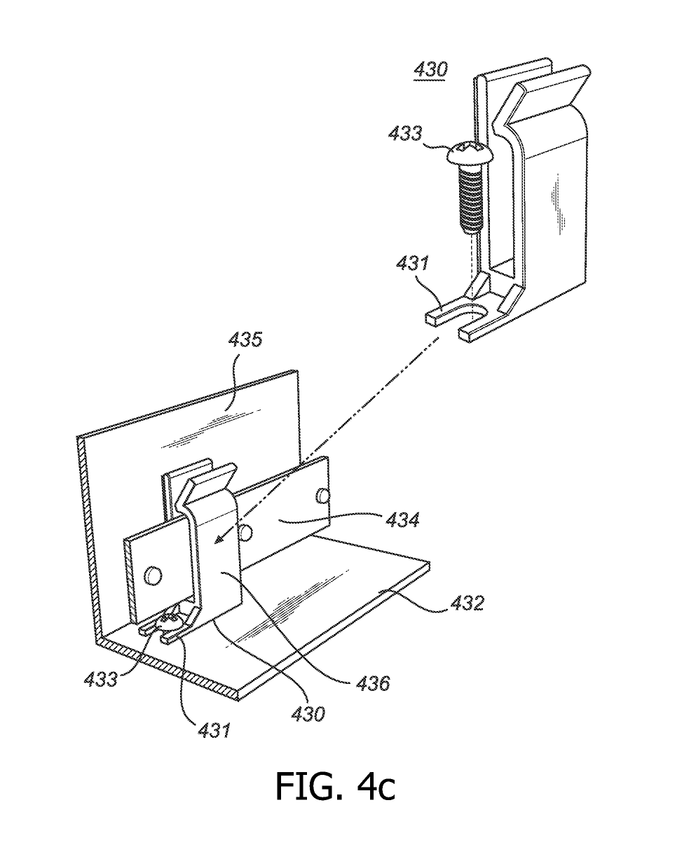

In FIGS. 4a and 4b, two embodiments of clips are shown that are adapted for mounting on curved surfaces 401 and 402, respectively. In general, the shape of the clip, or the resilient part of the clip, is arranged to clamp or hold the LED strip. The cross section of the clip, or the resilient part of the clip, can, e.g., have a distorted U-shape. The clip 410 shown in FIG. 4a has a base 411 of elongated shape, whereas the clip 420 shown in FIG. 4b has a split base with two elongated parts 421′ and 421″ that are bendable. The clip can be mounted to a wall in a variety of ways, e.g., by gluing or by using self-adhesive tape 412, but can also be attached to the channel sign using screws.

In FIG. 4c, a third embodiment of the clip is shown. The clip 430 has a base 431 that can be mounted to the rear wall 432 of a channel sign using a screw 433. Mounting the clip to the rear wall 432 is advantageous in that the LED strip 434 can be kept at a certain distance to the side wall 435. The base 431 extends from the resilient part 436 of the clip along the line of extension of the LED strip 434, such that the screw 433 is offset from the resilient part 436 correspondingly. This is advantageous in that the space requirements for mounting the clip are kept at minimum and that it can be mounted in narrow channels. Using the clip 430 for mounting a LED strip to the rear wall is advantageous in that the LED strip 434 is oriented the same way as if it would have been mounted to the side wall using any of the clips 410 or 420, respectively, i.e., such that the FCB is facing the side wall.

In general, the clip can be made of any material, e.g., plastic, and is preferably transparent in order to not obstruct the emitted light and/or create shadows. Using clips instead of mounting the LED strip directly to an interior surface of the channel sign has the advantage that the LED strip can easily be repositioned or replaced. Furthermore, since standard glues generally do not stick to silicon, a more reliable connection is achieved if clips are used.

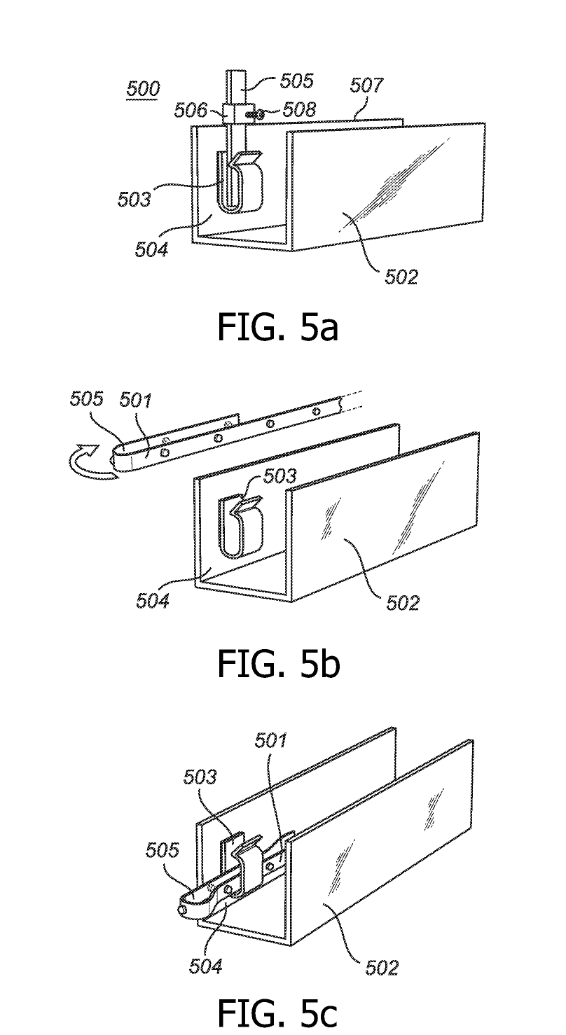

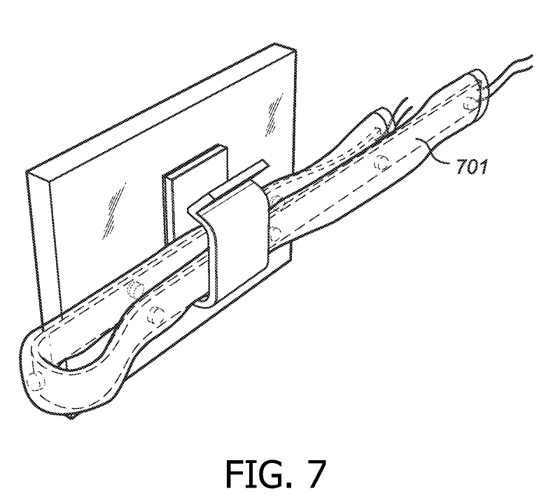

FIGS. 5a to 5c show a sequential diagram illustrating a method 500 for mounting a flexible LED strip 501 in a channel sign 502. The LED strip 501 can be any flexible LED strip that is foldable, e.g., any of the LED strips described above with reference to FIGS. 1-3, or a LED strip 701 encapsulated in a flexible sleeve or tube, such as shown in FIG. 7. The flexible sleeve or tube renders the LED strip waterproof. It will be appreciated that the use of a flexible sleeve or tube is advantageous in that, the LED strip length can be adjusted by folding and, at the same time, the waterproof encapsulation is retained.

First, as shown in FIG. 5a, a clip 503 is attached to an interior surface 504 of the channel sign 502 using self-adhesive tape. This latter approach facilitates the mounting in small channel signs since it is difficult to access the interior of a small channel with a tool such as a screwdriver. The clips can be mounted using a tool 505 specifically adapted for that purpose but might also be mounted using a standard tool (such as a ruler) or by hand. The tool 505 can, e.g., be of oblong shape and may comprise a stop 506 that defines the mounting position of the clip with respect to the upper edge 507 of the channel's side wall. The stop 506 can be arranged such that it is movable along the tool and can be fixated with, e.g., a screw 508. This has the advantage that the mounting position (i.e., the distance between the clip and the upper edge 507 of the channel's side wall) is adjustable.

In the next step, FIG. 5b, an end 505 of the LED strip 501 is folded back to adjust the length of the LED strip 501.

In the final step, shown in FIG. 5c, the LED strip 501 is fixated by inserting the strip into clip 503. Fixating the LED strip is facilitated by inserting it at a region where no resin is applied or where the resin is thinner, since the strip is more easily accommodated by the resilient clip 503.

Note that the steps of the method described above do not necessarily have to be performed in the prescribed order. In fact, the LED strip 501 can first be fixated using the clip 503 attached to the channel wall 504. In a subsequent step, and end 505 of the LED strip 501 can be fixated by inserting it into the same clip 503 that was used to mount the LED strip 501.

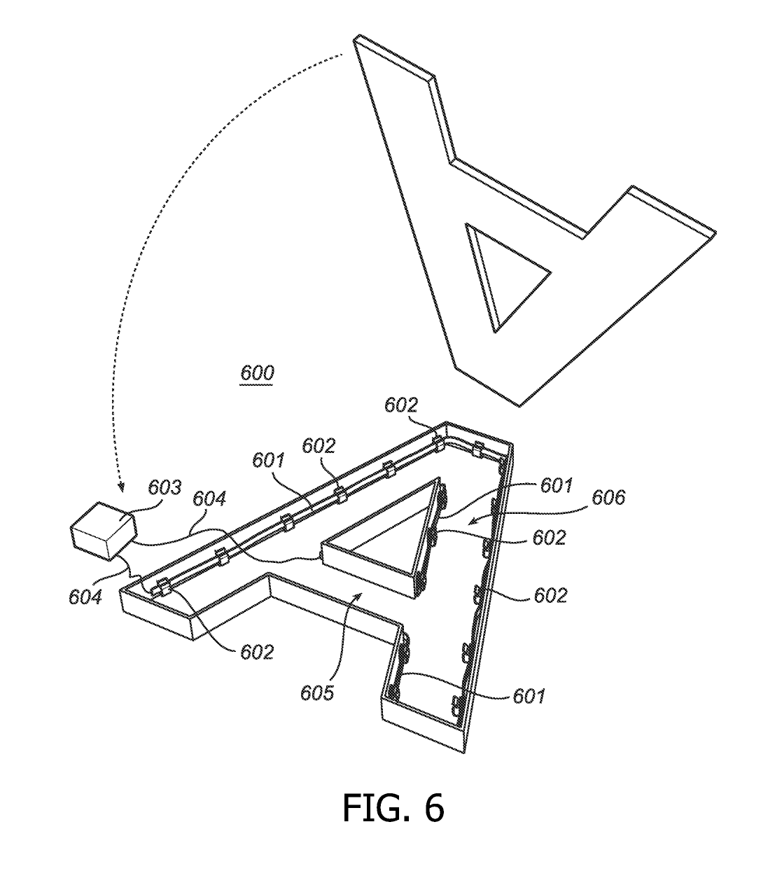

FIG. 6 shows a channel sign 600 with LED strips 601 mounted to interior side walls of the channel sign 600 using clips 602. The clips 602 may be any of the clips described with reference to FIGS. 3 to 5 in the above. The LED strips 601 are connected to a power supply 603 using cables 604. Depending on the width of the channel and/or the required illumination, LED strips 601 can be mounted only on one side of the channel, as in region 605, or on both sides of the channel, as in region 606.

The person skilled in the art realizes that the present invention by no means is limited to the embodiments described above. On the contrary, many modifications and variations are possible within the scope of the appended claims. For example, the additional electronic components that the LED strip might be equipped with can be mounted to the PCB in a region that is separate from where the LEDs are mounted, e.g., close to the connector or at one of the ends of the LED strip. Furthermore, the clips that are used for mounting a LED strip can be arranged for mounting using any one or a combination of glue, self-adhesive tape, screws, nails, or rivets.

In conclusion, a LED strip for the illumination of channel signs is provided. The LED strip comprises a flexible circuit board, a plurality of LEDs mounted on the circuit board, and an electrical connector for connecting the LED strip to a power supply. The LED strip is at least in part encapsulated by a flexible resin such that the LED strip is foldable. The LED strip according to the present invention is advantageous in that its length can be adjusted by folding instead of cutting, thereby retaining the waterproof encapsulation of the LED strip. Further, a method for mounting a flexible LED strip in a channel sign is provided. The method comprises the steps of attaching at least one clip to an interior surface of the channel sign, folding back an end of the LED strip, and fixating the LED strip including the folded end using the clip. The method according to the present invention is advantageous in that it provides an easier and more reliable mounting of a LED strip as compared to standard prior art techniques.

1. An LED strip, comprising:
a flexible circuit board,
a plurality of LEDs mounted on said circuit board, and
an electrical connector for connecting said LED strip to a power supply,
said LED strip being encapsulated at least in part by a flexible material such that said LED strip is foldable.

2. The LED strip according to claim 1, further comprising a plurality of electronic components mounted to said circuit board, wherein at least one region between two adjacent LEDs is free from said electronic components.

3. The LED strip according to claim 2, wherein said material is applied only proximate to said electronic components and said LEDs.

4. The LED strip according to claim 1, wherein said material is thinner within at least one region between two adjacent LEDs than proximal to said LEDs.

5. A channel sign comprising:
at least one LED strip according to claim 1, and
at least one clip for fixating said LED strip, said clip attached to an interior surface of said channel sign.

6. A method for mounting a flexible LED strip in a channel sign, said method comprising the steps of:
attaching at least one clip to an interior surface of said channel sign,
folding back an end of said LED strip, and
fixating the LED strip including said end using said clip.

7. The method according to claim 6, wherein said interior surface is a side wall of said channel sign.

8-10. (canceled)

11. The method according to claim 6, wherein said LED strip is arranged in a flexible sleeve such that said LED strip is foldable.

12. The method according to claim 6, wherein said LED strip is encapsulated at least in part in a flexible resin such that said LED strip is foldable.

13. The LED strip according to claim 1, wherein said material comprises a resin.
